(19) United States
(12) Patent Application Publication
(10) Pub. No.: US 2024/0146007 A1
(43) Pub. Date: May 2, 2024

(54) ELECTRICAL CONNECTOR, ANTENNA SYSTEM AND ASSOCIATED METHODS

(71) Applicant: AGC GLASS EUROPE, Louvain-la-Neuve (BE)

(72) Inventors: Hà BUI-VAN, Louvain-La-neuve (BE); Peter SCHNÖRCH, Bruxelles (Uccle) (BE); Remi SARKIS, Louvain-La-Neuve (BE); Raphaël DERUETTE, Gosselies (BE)

(73) Assignee: AGC GLASS EUROPE, Louvain-la-Neuve (BE)

(21) Appl. No.: 18/574,625

(22) PCT Filed: Jun. 29, 2022
(86) PCT No.: PCT/EP2022/067855

§ 371 Date: Dec. 27, 2023

(30) Foreign Application Priority Data
Jul. 2, 2021 (EP) 21183413.0

(51) Int. Cl. H01R 24/52; H01R 9/05; H01R 13/6593

(52) U.S. Cl. CPC H01R 24/52; H01R 9/0524; H01R 13/6593

(57) ABSTRACT

An electrical connector for electrically connecting a coaxial cable to an antenna disposed on a thin support, the coaxial cable including a pin and a shield separated by a dielectric element and protected by an insulated layer. The electrical connector includes a shield part having at least one leg and a bridge to clamp the shield between the bridge of the shield part and the antenna and to electrically connect the shield to the antenna. The electrical connector also includes a pin part having at least one leg and a bridge to clamp the pin between the bridge of the pin part and the antenna and to electrically connect the pin to the antenna. The pin part is electrically isolated from the shield part. Each of the at least one leg of the shield part includes at least a penetration means designed to penetrate through the thin support.

### TECHNICAL FIELD

The present application relates to an electrical connector to facilitate the feeding of an antenna disposed on a thin support. The present application relates also to an antenna system comprising such electrical connector.

### BACKGROUND ART

Mobile data traffic is increasing continuously and will boom significantly with 5G, putting mobile network operators under CAPEX pressure. Higher frequency bands for 5G mean more challenges for coverage deployment, especially in dense urban areas where capacity will be needed and strict EMF limitations apply. The deployment of small cells are described as a good solution for capacity improvement which requires to install a large number of antennas in order to stably perform electromagnetic wave transmission and reception.

However, many drawbacks limit the deployment of small cells. First, it is very difficult to find location for new antennas. Second, bringing fiber and electricity outdoor is costly. Finally, urbanistic regulations may limit possibilities for small cells.

On top of that, with the advent of connected and autonomous vehicles, the number of required onboard antennas is ever increasing, and finding suitable locations becomes more and more complicated especially for Wi-Fi, 4G, 5G and DSRC, DTV, FM, . . . .

In a vehicle, antenna are usually placed on a glazing or on the roof inside a shark fin, or a roof module.

To connect to a functional system and to feed an antenna, an electrical connector is used between the coaxial cable and the antenna.

Existing connectors on the market are based on soldering techniques to make the connection for the antenna to the connector.

WO2016174228 discloses a specific electrical connector to electrically connect a coaxial cable to an antenna. Such electrical connectors are soldered on the antenna to feed it.

Antenna can be disposed on a substrate such as glass or thin support.

However, with low-temperature resistance substrate such as a thin support, the substrate cannot withstand the high-temperature of the soldering.

To avoid this low-temperature resistance of thin support, the electrical connector is usually glued with a conductive glue to the antenna. This solution however has an issue of mechanical resistance, which can be removed from the support causing disconnections, quality issues, aging problems, . . . .

### SUMMARY OF INVENTION

The present invention relates, in a first aspect, to an electrical connector for electrically connecting a coaxial cable, which comprises a pin and a shield separated by a dielectric element and protected by an insulated layer, to an antenna disposed on a thin support.

The present invention relates, in a second aspect, to antenna system comprising a thin support, an antenna disposed on a thin support, a coaxial cable which comprises a pin and a shield separated by a dielectric element and protected by an insulated layer and an electrical connector according to the first aspect of the invention.

The solution as defined in the first aspect and in the second aspect of the present invention is based on that the electrical connector comprises:
a shield part (101) comprising at least one leg (102, 103) and a bridge (104) clamping the shield between the bridge of the shield part and the antenna to electrically connect the shield to the antenna, preferably the shield part comprises two legs (102, 103) separated by the bridge (104)) clamping the shield between the bridge of the shield part and the antenna to electrically connect the shield to the antenna and
a pin part (201) comprising at least a leg (202, 203) and a bridge (204) clamping the pin between the bridge of pin part and the antenna and to electrically connect the pin to the antenna, the pin part is electrically isolated from the shield part, preferably the pin part comprises two legs (202, 203) separated by the bridge (204) clamping the pin between the bridge of pin part and the antenna and to electrically connect the pin to the antenna, the pin part is electrically isolated from the shield part.

Preferably, to facilitate the handling and the stability of the electrical connector, the shield part comprises two legs separated by the bridge.

The solution as defined in the first aspect and in the second aspect of the present invention is also based on that each of the at least one leg of the shield part, preferably each of the two legs of the shield part, comprises at least a shield part's penetration means designed to penetrate through the thin support and on that the at least a shield part's penetration means and the at least one leg of the shield part, preferably the two legs of the shield part, are not coplanar.

By penetrating through the thin support, the shield part's penetration means and the pin part's penetration means, mechanically maintains the electrical connector to the thin support while the coaxial cable is electrically connected to the antenna.

The present invention relates, in a third aspect, to a vehicle comprising an antenna system according to the second aspect of the present invention.

The present invention relates, in a fourth aspect, to a method for connecting a coaxial cable, which comprises a pin and a shield separated by a dielectric element and protected by an insulated layer, to an antenna disposed on a thin support with an electrical connector.

The solution as defined in the fourth aspect of the present invention is based on that the method comprises the electrical connector comprises:
a shield part (101) comprising at least one leg (102, 103) and a bridge (104) clamping the shield between the bridge of the shield part and the antenna to electrically connect the shield to the antenna, preferably the shield part comprises two legs (102, 103) separated by the bridge (104)) clamping the shield between the bridge of the shield part and the antenna to electrically connect the shield to the antenna and
a pin part (201) comprising at least a leg (202, 203) and a bridge (204) clamping the pin between the bridge of pin part and the antenna and to electrically connect the pin to the antenna, the pin part is electrically isolated from the shield part, preferably the pin part comprises two legs (202, 203) separated by the bridge (204) clamping the pin between the bridge of pin part and the antenna and to electrically connect the pin to the antenna, the pin part is electrically isolated from the shield part.

Preferably, to facilitate the handling and the stability of the electrical connector, the shield part comprises two legs separated by the bridge.

The method further comprises each of the at least one leg of the shield part, preferably each of the two legs of the shield part, comprises at least a shield part's penetration means designed to penetrate through the thin support and on that the at least a shield part's penetration means and the two legs of the shield part are not coplanar.

The solution as defined in the fourth aspect of the present invention is also based on that the method comprises the method comprises following steps:
A) positioning the coaxial cable over the antenna
B) pressing the at least a shield part's penetration means through the thin support to clamp the shield between the bridge of the shield part and the antenna to electrically connect the shield to the antenna.

Surprisingly, this solution according to the first, second, third and fourth aspects permits to improve the mechanical resistance while improving the handling reducing quality issues and aging problems thanks to the shield part's penetration means penetrating through the thin support the electrical connector.

Thus, the electrical system according to the invention permits to electrically connect a coaxial cable to an antenna disposed on a thin support in an easy, fast and durable way.

The present invention increases quality and the durability of an antenna system according to the second aspect.

Furthermore, the electrical connector helps the contact with the antenna surface and resist to any movement.

Therefore, the present invention solves the need to find new location to place systems while allowing greater handling and quality.

The present invention improves the connectivity between the antenna and the coaxial cable while protecting parts of the cable and the cable itself.

The present invention permits to save manufacturing and assembling time.

The present invention permits to save money compared to existing solutions.

The present invention also improves the accuracy of the connection between the coaxial cable and the antenna.

Other advantages will be explained in the followings description.

It is noted that the invention relates to all possible combinations of features recited in the claims or in the described embodiments.

The following description relates to vehicle applications but it's understood that the invention may be applicable to others fields like transportation applications, other road users and/or services and buildings applications.

### BRIEF DESCRIPTION OF THE DRAWINGS

This and other aspects of the present invention will now be described in more detail, with reference to the appended drawings showing various exemplifying embodiments of the invention which are provided by way of illustration and not of limitation. The drawings are a schematic representation and not true to scale. The drawings do not restrict the invention in any way. More advantages will be explained with examples.

FIG. 1 is a schematic 3D view from the top of an electrical connector according to the first aspect of the invention.

FIG. 2 is a schematic 3D view from the top of an antenna system according to the second aspect of the invention.

FIG. 3 is a schematic 3D view from the bottom of an antenna system according to the second aspect of the invention.

FIG. 4 is a schematic view from a side of an antenna system according to the second aspect of the invention.

FIG. 5 is a schematic 3D view from the top of an electrical connector according to the first aspect of the present invention penetrating trough an antenna disposed on a thin support according to the invention.

FIG. 6 is a schematic 3D view from the top of an antenna system according to the second aspect of the invention.

### DETAILED DESCRIPTION

In this document to a specific embodiment and include various changes, equivalents, and/or replacements of a corresponding embodiment. The same reference numbers are used throughout the drawings to refer to the same or like parts.

As used herein, spatial or directional terms, such as “inner”, “outer”, “above”, “below”, “top”, “bottom”, and the like, relate to the invention as it is shown in the drawing figures. However, it is to be understood that the invention can assume various alternative orientations and, accordingly, such terms are not to be considered as limiting. Further, all numbers expressing dimensions, physical characteristics, processing parameters, quantities of ingredients, reaction conditions, and the like, used in the specification and claims are to be understood as being modified in all instances by the term “about”. Accordingly, unless indicated to the contrary, the numerical values set forth in the following specification and claims are approximations that can vary depending upon the desired properties sought to be obtained by the present invention. In the following description, unless otherwise specified, expression “substantially” mean to within 10%, preferably to within 5%.

Moreover, all ranges disclosed herein are to be understood to be inclusive of the beginning and ending range values and to encompass any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more, e.g. 1 to 6.1, and ending with a maximum value of 10 or less, e.g., 5.5 to 10. Further, as used herein, the terms “deposited over” or “provided over” mean deposited or provided on but not necessarily in surface contact with. For example, a coating “deposited over” a substrate does not preclude the presence of one or more other coating films of the same or different composition located between the deposited coating and the substrate.

Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated. In this document, “configured to (or set to)” may be interchangeably used in hardware and software with, for example, “appropriate to”, “having a capability to”, “changed to”, “made to”, “capable of”, or “designed to” according to a situation. In any situation, an expression “device configured to do” may mean that the device “can do” together with another device or component.

Furthermore, the terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein. When it is described that a constituent element (e.g., a first constituent element) is “(functionally or communicatively) coupled to” or is “connected to” another constituent element (e.g., a second constituent element), it should be understood that the constituent element may be directly connected to the another constituent element or may be connected to the another constituent element through another constituent element (e.g., a third constituent element).

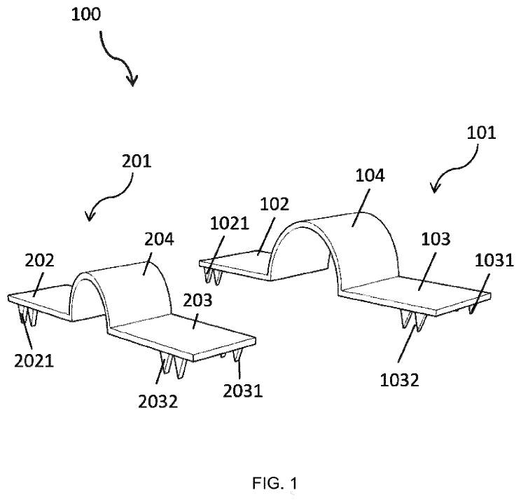

According to a first aspect of the invention, as illustrated in FIG. 1, the electrical connector 100 is designed to electrically connect a coaxial cable, which comprises a pin and a shield separated by a dielectric element and protected by an insulated layer, to an antenna disposed on a thin support.

The electrical connector 100 comprises a shield part 101 and a pin part 201. The pin part is electrically isolated from the shield part.

The shield part 101 comprising at least one leg 102, 103 and a bridge 104 designed to clamp a shield of a coaxial cable between the bridge of the shield part and an antenna disposed on a thin support and to electrically connect the shield to the antenna. FIG. 1 illustrated embodiments where the shield part 101 comprises two legs 102, 103 separated by the bridge 104.

Each of the two legs 102, 103 of the shield part 101 comprises at least a shield part's penetration means 1031, 1032, 1021, 1022 designed to penetrate through a thin support. The at least a shield part's penetration means 1031, 1032, 1021, 1022 and the two legs of the shield part are not coplanar to penetrate through a thin support and to electrically connect the coaxial cable to an antenna disposed on the thin support, i.e. the at least a shield part's penetration means 1031, 1032, 1021, 1022 are provided on the surface of the legs of the shield part facing the thin support.

According to the invention, the shield part's penetration means of each leg comprises a tine to penetrate through at least a thin support. More preferably, the shield part's penetration means of each leg comprises a plurality of tines to facilitate to penetration through at least a thin support.

As illustrated in FIG. 1, the pin part 201 comprising two legs 202, 203 separated by a bridge 204 designed to clamp a pin of a coaxial cable between the bridge of the pin part and an antenna disposed on a thin support and to electrically connect the pin to the antenna. The at least a pin part's penetration means 2031, 2032, 2021, 2022 and the two legs of pin part are not coplanar to penetrate through a thin support and to electrically connect the coaxial cable to an antenna disposed on the thin support, i.e. the at least a pin part's penetration means 2031, 2032, 2021, 2022 are provided on the surface of the legs of the pin part facing the thin support.

According to some preferred embodiments of the invention, the pin part's penetration means of each leg comprises a tine to penetrate through at least a thin support. More preferably, the pin part's penetration means of each leg comprises a plurality of tines to facilitate to penetration through at least a thin support.

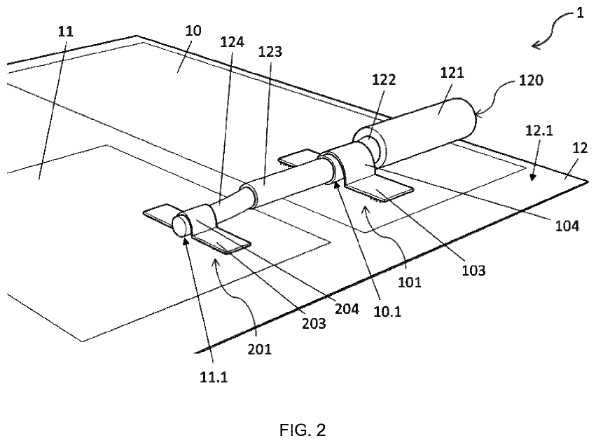

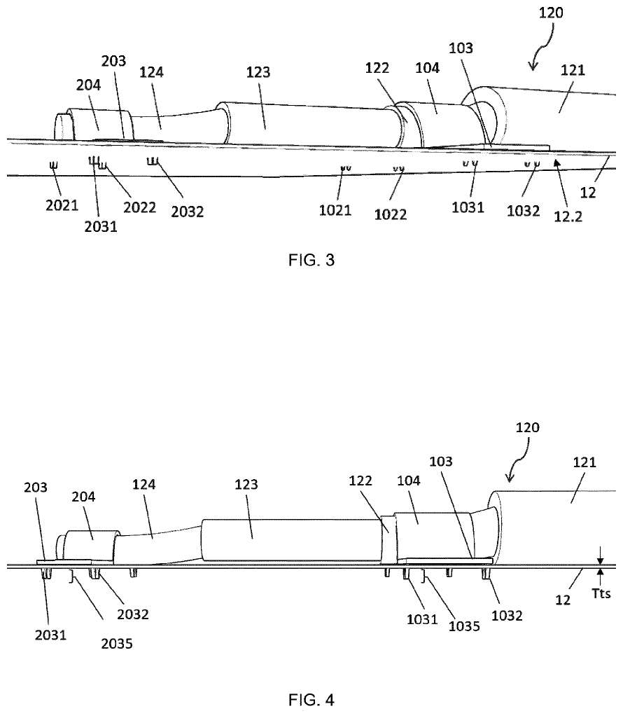

FIGS. 2 to 4 illustrates an antenna system 1 comprising a thin support 12, an antenna 10, 11 disposed on the thin support. The antenna system comprises a coaxial cable 120 which comprises a pin 124 and a shield 122 separated by a dielectric element 123 and protected by an insulated layer 121.

The thin support can take different forms and shapes, where its dimension (length and/or width) is varied, which can be between a millimeter to few meters.

The term thin support means a support having a thickness equals to or lower than 5 mm, preferably equals to or lower than 3 mm.

Depending on the application, the thin support has a thickness, Tts, comprised between 10 μm and 3 mm (0.01 mm≤Tts≤3 mm) to be penetrated. Depending on the application, the thickness can be 20 μm, 50 μm, 75 μm, 75 μm, 100 μm 125 μm, 150 μm or any specific value.

In some preferred embodiments, the thickness of the thin support is comprised between 20 μm and 250 μm (0.02 mm≤Tts≤0.25 mm).

According to the invention, the thin support can be a mono-layer or a multilayers structure of the same or of different materials, where the antenna can be deposited on. In is understood that the thin support functions as a dielectric substrate for the antenna.

The thin support is preferably a thin plastic support. The thin support can be any dielectric material used in printed circuit or a more flexible material used as flexible substrate, such as a polymer, a plastic, a laminated materials or any other suitable material such as Polyethylene—PE, Polyethylene terephthalate—PET, polystyrene—PS, polyamide—PA, polyvinyl chloride—PVC, polycarbonate—PC, Polypropylene—PP, polyethylene furanoate—PEF. Preferably, the thin support comprises PET, but can be any other plastic materials depending on the application and the way to fix the thin support on an object, the needed durability due to external exposition such as sun, temperature, . . . .

The thin support comprises a top surface 12.1 and a bottom surface 12.2. The antenna 10, 11 is disposed on the top surface 12.1 of the thin support.

As illustrated in figures, the antenna can comprises two parts 10, 11. These two parts are electrically isolated.

The-pin 124 of the coaxial cable 120 is connected to one of the two parts 11 and the shield 122 of the coaxial cable 120 is connected to the other part 10 of the two parts.

The antenna 10, 11 is disposed on the thin support. The term “disposed on” means that the antenna can be a conductive layer printed, screen printed, inkjet printed, deposited or other similar methods suitable to disposed an antenna on a thin support. The antenna can also be realized using etching or laser de-coating technologies to design the antenna by creating nonconductive areas. The antenna can also be made of metal mesh film, consisting of several thin connected wires forming the antenna shape or a printed circuit.

According to the invention, the antenna is made of conductive material. The materials for making antenna can be of any high-conductivity material such as but not limited to copper, silver, copper ink.

In some preferred embodiments, the antenna can be an antenna. The antenna is preferably multiple-bands antenna used for communication such as Wi-Fi, FM, AM, TV, remote key entry (RKE), telematics/cellular antennas such as 2G, 3G, 4G, 5G, satellite, GPS navigation, V2X, DSRC, or any other radio broadcast applications. In multiple bands antenna embodiments, the antenna can comprises two parts 10, 11, a radiation part 10 designed to act as a radiating element and a ground part 11 designed to act as a ground plate.

It is understood that the shape of the antenna is not limited to rectangular shapes. The antenna itself, and each part of the antenna 10, 11 according to the invention can have any shape according to required parameters such as performances, frequencies, wavelengths, available surface, . . . .

To electrically connect the coaxial cable 120 to the antenna 10, 11 while mechanically maintain the coaxial cable 120 on the thin support 12, the antenna system further comprises a electrical connector according to the first aspect of the invention.

The electrical connector comprises a shield part 101 comprising two legs 102, 103 separated by a bridge 104 clamping the shield 122 between the bridge 104 of the shield part and the antenna 10 to electrically connect the shield to the antenna and a pin part 201 comprising two legs 202, 203 separated by a bridge 204 clamping the pin 124 between the bridge 204 of pin part and the antenna and to electrically connect the pin 124 to the antenna 11. The pin part 201 is electrically isolated from the shield part 101.

The two legs of the shield part comprises at least a shield part's penetration means 1031, 1032, 1021, 1022 penetrating through the thin support 12. The at least a shield part's penetration means 1031, 1032, 1021, 1022 and the two legs of the shield part are not coplanar.

The shield part's penetrating means 1031, 1032, 1021, 1022 has at least a part 1035 that fully passes through the thin support and comes out of the opposite face from the penetration, the bottom surface 12.2. Such parts 1035 can own notches or hook-like shape to prevent the electrical connector from being withdrawn. This part 1035 can also be folded on the bottom surface 12.2 after the penetration through it.

The shield part's penetration means and the pin part's penetration means, if exists, permits to clamp the antenna between the electrical connector and the thin support to ensure electrical connection between the shield and the ground part and to ensure electrical connection between the pin and the radiation part.

In some embodiments, such parts 1035 having passed through the support can be bent over the opposite surface to the penetration of the thin support to ensure the mechanical strength of the system. Even if some parts are bent, the shield part's penetration means and the pin part's penetration means are not coplanar with the legs.

According to the invention, legs can have a shape of a rectangular, a triangle or any polygon shape, where the contact surface, interacting against the antenna and thin support, can be from 0.1 mm² to about 10 cm².

The bridge can have a generic shape of an inverse U-shape, a staircase shape or a rectangular shape, with a width of the bridge is between 0.1 mm to a about 10 cm, the height from 0.1 mm to about 10 cm. The thickness of the legs and the bridge is between 0.1 mm to 2 cm. Preferably the thicknesses are at most 5 mm.

In some embodiments, legs can have a 1.5 mm×3 mm rectangle shape, the bridge height can be 1.5 mm.

According to the invention, the electrical connector is attached to the thin support, thus the legs of the shield part 102, 103 are mechanically attached to one part 301, 302 of the thin support and the antenna; at the same time, the bridge of the shield part 104 presses the shield part of the coaxial cable against the antenna part on the thin support. Therefore, the electrical contact 10.1 between the shield part 122 of the coaxial cable and the antenna 10 is made via direct contact between the shield part and the antenna part, as well as via the bridge and the legs of the shield part of the electrical conductive electrical connector, for the case the bridge and the legs of the shield part are conductive.

In a similar manner, in some embodiments according to the invention, the legs of the pin part 202, 203 are mechanically attached to another part 401, 402, 403, 404 of the thin support and the antenna, and the bridge of the pin part 204 clips the pin of the coaxial cable with another antenna part 11 on the thin support. Thus, the electrical contact 11.1 between the antenna 11 and the pin 124 of the coaxial cable is made via their direct contact as well as via the bridge and the legs of the pin part of the electrical conductive electrical connector, for the case the legs and the bridge of the pin part are conductive.

The two legs on either the pin part, in some embodiments, and the shield part can have the same shape or different shapes.

Preferably, the two legs of the shield part, preferably, have a same shape and dimension as to keep the stability of the cable. Moreover, as the shape and the dimension are the same for the two legs, the electrical contact is balance of both side of the connection, which further improve the performance of the antenna. In some embodiments, such as when a balun structure is used or when a co-planar-waveguide structure is present. Lately, the symmetry of the legs can give an advantage of the design of the tooling to clamp the legs against the thin support, as well as in the operation/manipulation.

Preferably, the two legs of the pin part, preferably, have a same shape and dimension as to keep the stability of the cable. Moreover, as the shape and the dimension are the same for the two legs, the electrical contact is balance of both side of the connection, which further improve the performance of the antenna. In some embodiments, such as when a balun structure is used or when a co-planar-waveguide structure is present. Lately, the symmetry of the legs can give an advantage of the design of the tooling to clamp the legs against the thin support, as well as in the operation/manipulation.

According to the invention and as illustrated in FIG. 2, the shield part clamps the shield 122 to the antenna 10 to create an contact area 10.1 between the shield 122 and the antenna 10 the electrically connect the shield 122 to the antenna 10. The pin part clamps the pin 124 to the antenna 11 to create an contact area 11.1 between the pin 124 and the antenna 11 the electrically connect the pin 124 to the antenna 11.

Thus, the shield part and/or the pin part can be made of conductive materials or nonconductive materials, to create cheap and easy alternative solution compared to the soldering or conductive gluing, the electrical connection between the coaxial cable and the antenna is done by the physical contact between the shield and the antenna realized by the clamping a part of the cable to the antenna allowing to use non-conductive material.

In some preferred embodiments, the shield part and/or the pin part comprises conductive materials. Preferably, conductive material are at least on surfaces.

The shield part's penetration means and/or pin part's penetration means can be made of a conductor plated or not plastic-based material or can be made of a conductive based material such as Aluminum; copper alloys; beryllium copper; Phosphore bronze; brass; gold; nickel and nickel base alloys, silver or nickel plated stainless steel or any conductive material suitable to act as a conductor while able to penetrate a thin support. The pin part's penetration means can also be coated or surface-treated to improve the conductivity and/or the mechanical resistance.

In some other preferred embodiments, the shield part and/or the pin part comprises made of nonconductive materials to minimizing parasite in the transmission of the EM signal by the antenna through the coaxial cable. Preferably, nonconductive material are at least on surfaces.

In some embodiments, to easily handle the electrical connector, the electrical connector electrical connector can further comprise a maintain means (not shown) to maintain together the shield part 101 and the pin part 201. The maintain means can comprises at least a bar from the shield part to the pin part. This at least a bar can be fixed to a leg 103, 102 of the shield part to the corresponding leg respectively 203, 202, of the pin part. The element can be fixed to the bridge 104 of the shield part to the bridge 204 of the pin part. The maintain means can also be a plate fixed between the shield part 101 and the pin part 201.

The maintaining means can be made of any material able to maintain the shield part and the pin part excepts if the part of the shield part and the part of the pin part on which is fixed on are made of conductive material. In such case, the maintain means is made of nonconductive materials. Such nonconductive material can be Silicone-based, Epoxy-based, Acrylates-based, thermoplastic-based such as PU, ABS, PC-ABS, HDPE.

It is understood that the shield part's penetration means can also penetrate through an antenna disposed on a thin support and through the thin support.

In some embodiments according to the invention, the shield part's penetration means is directly fixed to the dielectric substrate. In such embodiments, the shield part's penetration means is preferably nonconductive. The electrical connection of the antenna is made by physical contact between the antenna and the shield and the pin.

In some embodiments, each of the legs of the shield part has a shield part's penetration means.

In some embodiments, the shield part's penetration means comprises a tine to penetrate through at least the a thin support. More preferably, the shield part's penetration means comprises a plurality of tines to facilitate to penetration through at least the a thin support.

The shield part's penetration means can also as a generic triangle shape, a hook-like shape, teeth-like shape or any shape that can penetrate through at least a thin support and more preferably through a thin support and an antenna disposed on the thin support. At least a part of the sides of the shield part's penetration means can be sharpen to facilitate the penetration.

According to the invention, the shield part's penetration means can have dimension ranging from submilimeter (0.1 mm) to 10 cm in width, and height ranging from 0.1 mm to 10 cm. The dimension can be also adapted for the required working frequencies of the antenna as well as the size of the electrical connection points to the antenna.

It is understood that the pin part's penetration means can also penetrate through an antenna disposed on a thin support and through the thin support.

In some embodiments, each of the legs of the pin part has a pin part's penetration means.

In some embodiments according to the invention, the pin part's penetration means is directly fixed to the dielectric substrate. In such embodiments, the pin part's penetration means is preferably nonconductive. The electrical connection of the antenna is made by physical contact between the antenna and the coaxial cable via the shield and the pin.

The two legs of the pin part comprises at least a pin part's penetration means 2031, 2032, 2021, 2022 penetrating through the thin support 12. The at least a pin part's penetration means 2031, 2032, 2021, 2022 and the two legs of the pin part are not coplanar.

The pin part's penetration means 2031, 2032, 2021, 2022 has at least a part 2035 that fully passes through the thin support and comes out of the opposite face from the penetration, the bottom surface 12.2. Such parts 2035 can own notches or hook-like shape to prevent the electrical connector from being withdrawn. This part 2035 can also be folded on the bottom surface 12.2 after the penetration through it.

The pin part's penetration means can also as a generic triangle, with or without cut corner, shape with or without notches, a hook-like shape, a teeth-like shape or any shape that can penetrate through at least a thin support and more preferably through a thin support and an antenna disposed on the thin support. At least a part of the sides of the pin part's penetration means can be sharpen to facilitate the penetration.

According to the invention, the pin part's penetration means can have dimension ranging from submilimeter (0.1 mm) to 10 cm in width, and height ranging from 0.1 mm to 10 cm. The dimension can be also adapted for the required working frequencies of the antenna as well as the size of the electrical connection points to the antenna.

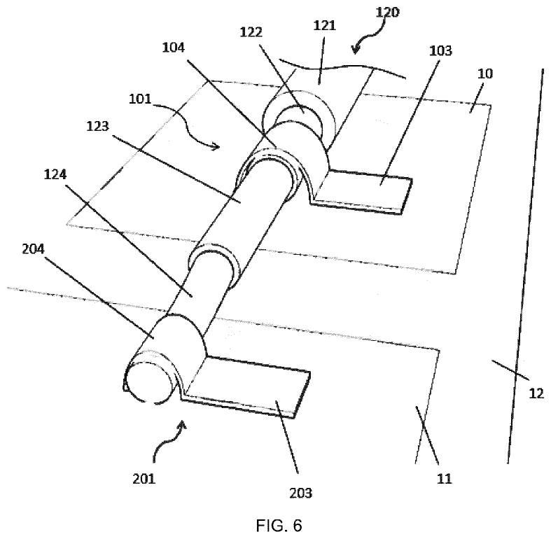

As illustrated in FIG. 6, in some embodiments according to the invention, the shield part 101 comprises one leg 103 and a bridge 104. The pin part 201 comprises one leg 203 and a bridge 204.

In such embodiments, the coaxial cable 120 is maintained between bridges 104, 204 and antenna 10, 11.

Preferably, in some preferred embodiments, the bridge 104 of the shield part 101 can crimped a part of the shield 122. Material is preferably conductive to improve the electrical connection between the shield 122 and the antenna 10. The bridge 204 of the pin part 201 can crimped a part of the pin 124. Material is preferably conductive to improve the electrical connection between the pin 124 and the antenna 11.

According to the invention, the leg of the shield part and the leg of the pin part can be in the same side of the coaxial cable or in an opposite side of the coaxial cable.

According to the invention, it is understood that the shield part and the pin part of the electrical connector are almost same in terms of structure and in function although they can differ in structure and/or in function in different embodiments, i.e. any embodiment related to the shield part and/or the shield part's penetration means can be applied to the pin part and/or the pin part's penetration means even if not directly disclosed in above embodiments. For example, a disclosure of a hook shaped shield part's penetration means in one embodiment should also be understood that the pin part's penetration means can also be hook shaped in the same or in any other embodiment.

The invention also relates to a vehicle comprising a least one antenna system, especially a multiple-bands antenna, according to the second aspect of the invention to install an antenna system on location where it was difficult to install an antenna system.

The system can be install on any other location where people needs to install an antenna, especially wide-bands antennas, disposed on a thin support. Antenna system can be placed on a surface of a glazing panel, such as a windshield, a sidelite, a roof, a backlite on a plastic part of a vehicle such as a spoiler, a B-pillar, a bumper, . . . . The antenna system can also be placed in front of such element to avoid to fix the system directly on the surface of it.

An embodiment provides a method for connecting a coaxial cable 120, which comprises a pin 124 and a shield 122 separated by a dielectric element 123 and protected by an insulated layer 121, to an antenna disposed on a thin support with an electrical connector according to the first aspect of the invention to create an antenna system according to the second aspect of the present invention.

The method comprises a positioning step of positioning the coaxial cable over the antenna, especially the shield over a first part of the antenna 10 and the pin over the second part of the antenna 11.

The method comprises a pressing step of pressing the at least a shield part's penetration means through the thin support to clamp the shield between the bridge of the shield part and the antenna to electrically connect the shield to the antenna.

It is understood that if a pin part's penetration means exists, the method can comprise also a second pressing step of pressing the pin part's penetration means through the thin support to clamp the pin between the bridge of the pin part and the antenna to electrically connect the pin to the antenna.

It is understood that pressing steps can be made in the same time or one before the other pressing steps. Preferably the pressing step of the shield part's penetration means is made before or at the same time than the pressing step of the pin part's penetration means.

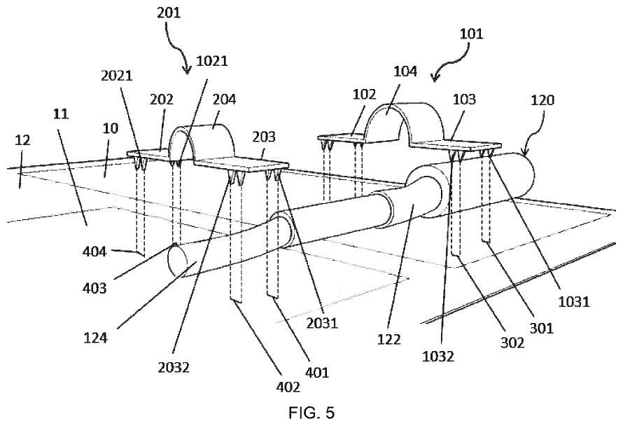

As illustrated in FIG. 5, the pressing steps of the shield part's penetration means allows the shield part's penetration means to perforate 301, 302 the thin support and eventually the antenna to create electrical connection between the antenna and the shield of the coaxial cable by clamping. The pressing steps of the pin part's penetration means allows the pin part's penetration means to perforate 401, 402, 403, 404 the thin support and eventually the antenna to create electrical connection between the antenna and the pin of the coaxial cable by clamping.

The method can comprises a bending step to bend parts 1035 of the shield part's penetration means having passed through the support comes out of the opposite face from the penetration. This step can be made during or after the corresponding pressing step.

The method can comprises a bending step to bend parts 2035 of the pin part's penetration means having passed through the support comes out of the opposite face from the penetration. This step can be made during or after the corresponding pressing step.

The method can comprises an overmolding step after the pressing steps and the bending steps to firmly fix the coaxial cable to the thin support, to ensure the electrical connection, to reduce corrosion issues and in the same time reduce risks of pull off. This step comprises a sub-step of placing the system into a mold having a two molding parts, a sub-step of closing these two molding parts to form a closed space around the system and a sub-step of injecting a plastic-based material into the closed space to form a overmolded element over at least a part of the system, preferably over at least the part.

The overmolding part allows to reduce the aging issues, increase the tightness of the system while reducing pulling out issues.

The plastic-based material can be made of a thermoplastic material, polyurethane (PU), polyamide, acrylic, polycarbonate, polyoxymethylene (POM), Polystyrene (PS), Acrylonitrile butadiene styrene (ABS), Polypropylene (PP), Polyethylene (PE), thermoplastic polyurethane (TPU), thermoplastic rubber (TPR), an epoxy, an acrylic resin or any suitable material to be injected into a mold. The temperature, the pressure can be adapted to be adapted to a specific embodiment.

An embodiment provides a use of an system according to the second aspect to let a user or a vehicle to communicate with his environment.

1: An electrical connector for electrically connecting a coaxial cable to an antenna disposed on a thin support, the coaxial cable comprising a pin and a shield separated by a dielectric element and protected by an insulated layer, to an antenna (10, 11) disposed on a thin support (12), the electrical connector comprising:
a shield part comprising at least one leg and a bridge to clamp the shield between the bridge of the shield part and the antenna and to electrically connect the shield to the antenna; and
a pin part comprising at least one leg and a bridge to clamp the pin between the bridge of pin part and the antenna and to electrically connect the pin to the antenna, the pin part being electrically isolated from the shield part,
wherein the at least one leg of the shield part comprises at least a shield part's penetration means designed to penetrate through the thin support, and
wherein the at least a shield part's penetration means and the at least one leg of the shield part are not coplanar.

2: The electrical connector according to claim 1, wherein the shield part comprises two legs separated by the bridge.

3: The electrical connector according to claim 1, wherein the at least one leg of the pin part comprises at least a pin part's penetration means designed to penetrate through the thin support.

4: The electrical connector according to claim 1, wherein the pin part comprise two legs separated by the bridge.

5: The electrical connector according claim 1, wherein the shield part's penetration means comprises at least a tine.

6: The electrical connector according to claim 1, wherein the pin part's penetration means comprises at least a tine.

7: The electrical connector according to claim 1, wherein the electrical connector further comprises a maintain means to maintain together the shield part and the pin part.

8: An antenna system comprising a thin support, an antenna disposed on the thin support, a coaxial cable which comprises a pin and a shield separated by a dielectric element and protected by an insulated layer, and an electrical connector, the electrical connector comprising:
a shield part comprising at least one leg and a bridge clamping the shield between the bridge of the shield part and the antenna to electrically connect the shield to the antenna, and
a pin part comprising at least a leg and a bridge clamping the pin between the bridge of pin part and the antenna and electrically connect the pin to the antenna, the pin part being electrically isolated from the shield part, the pin part being electrically isolated from the shield part,
wherein at least one leg of the shield part comprises at least a shield part's penetration means penetrating through the thin support; and
wherein the at least a shield part's penetration means and the at least one leg of the shield part are not coplanar.

9: The antenna system according to claim 8, wherein the at least one leg of the pin part comprises at least a pin part's penetration means penetrating through the thin support.

10: A vehicle comprising a least one antenna system according to claim 8.

11: A method for connecting a coaxial cable, the coaxial cable comprising a pin and a shield separated by a dielectric element and protected by an insulated layer, to an antenna disposed on a thin support with an electrical connector, the electrical connector comprising:
a shield part comprising at least one leg and a bridge clamping the shield between the bridge of the shield part and the antenna to electrically connect the shield to the antenna, and
a pin part comprising at least a leg and a bridge clamping the pin between the bridge of pin part and the antenna and electrically connect the pin to the antenna, the pin part being electrically isolated from the shield part,
wherein at least one leg of the shield part comprises at least a shield part's penetration means designed to penetrate through the thin support;
wherein the at least a shield part's penetration means and the at least one leg of the shield part are not coplanar, and
the method comprising:
A) positioning the coaxial cable over the antenna, and
B) pressing the at least a shield part's penetration means through the thin support to clamp the shield between the bridge of the shield part and the antenna to electrically connect the shield to the antenna.
STOP

12: The method according to claim 11, further comprises a step of further comprising bending a part of the shield part's penetration means that passed through the thin support on a surface opposite to a surface of penetration of the thin support.

13: The method according to claim 12
wherein at least one leg of the pin part comprises at least a pin part's penetration means penetrating through the thin support, and
the method further comprising pressing the at least the pin part's penetration means through the thin support to clamp the pin between the bridge of the pin part and the antenna to electrically connect the pin to the antenna.

14: The method according to claim 13, further comprising bending a part of the pin part's penetration means that passed through the thin support on the surface opposite to the surface of penetration of the thin support.

15: The method according to claim 12, further comprising overmolding at least the electrical connector over the antenna.

16: The antenna system according to claim 8,
wherein the shield part comprises two legs separated by the bridge clamping the shield between the bridge of the shield part and the antenna to electrically connect the shield to the antenna, and
wherein the pin part comprises two legs separated by the bridge clamping the pin between the bridge of the pin part and the antenna to electrically connect the pin to the antenna.

17: The method according to claim 11,
wherein the shield part comprises two legs separated by the bridge clamping the shield between the bridge of the shield part and the antenna to electrically connect the shield to the antenna, and
wherein the pin part comprises two legs separated by the bridge clamping the pin between the bridge of the pin part and the antenna and electrically connect the pin to the antenna.
